(19) United States
(12) Patent Application Publication
(10) Pub. No.: US 2025/0218943 A1
(43) Pub. Date: Jul. 3, 2025

(54) SEMICONDUCTOR DEVICES

(71) Applicant: SAMSUNG ELECTRONICS CO., LTD., Suwon-si (KR)

(72) Inventors: Jungun KIM, Suwon-si (KR); Injae Bae, Suwon-si (KR); Jihoon Chang, Suwon-si (KR); Chaeseok Kwak, Suwon-si (KR); Taeyun Kim, Suwon-si (KR); Kyoseon Chol, Suwon-si (KR); Deokhwan Choi, Suwon-si (KR)

(73) Assignee: SAMSUNG ELECTRONICS CO., LTD., Suwon-si (KR)

(21) Appl. No.: 18/830,265

(22) Filed: Sep. 10, 2024

(30) Foreign Application Priority Data
Jan. 2, 2024 (KR) 10-2024-0000200

(51) Int. Cl. H01L 23/528; H10B 12/00

(52) U.S. Cl. CPC H01L 23/5283; H10B 12/315; H10B 12/482; H10B 12/488; H10B 12/50

(57) ABSTRACT

Provided is a semiconductor device including: a lower structure including a substrate, and a lower transistor on the substrate; an intermediate structure on the lower structure; and an upper structure on the intermediate structure, the upper structure including an upper transistor and a data storage structure, wherein the intermediate structure includes: an intermediate interlayer insulating layer on the lower structure; an intermediate interconnection structure including an intermediate plug and an intermediate interconnection portion on the intermediate plug, wherein the intermediate plug penetrates the intermediate interlayer insulating layer; an intermediate stopper layer including an intermediate stopper horizontal portion on the intermediate interlayer insulating layer, and an intermediate stopper extension portion extending from the intermediate stopper horizontal portion and covering a side surface and an upper surface of the intermediate interconnection portion; and an intermediate gap-fill insulating layer on an external side surface of the intermediate stopper extension portion and on the intermediate stopper horizontal portion of the intermediate stopper layer.

### CROSS-REFERENCE TO RELATED APPLICATION

The application claims benefit of priority to Korean Patent Application No. 10-2024-0000200 filed on Jan. 2, 2024 in the Korean Intellectual Property Office, the disclosure of which is incorporated herein by reference in its entirety.

### BACKGROUND

### 1. Field

The disclosure relates to a semiconductor device.

### 2. Description of Related Art

As demand for high performance, high speed, and/or multifunctionality of a semiconductor device increases, integration density of a semiconductor device has increased. In manufacturing a semiconductor device having a fine pattern in response to the trend of high integration density of a semiconductor device, it may be necessary to implement patterns having a fine width or a fine spacing.

### SUMMARY

Provided is a semiconductor device in which at least one intermediate structure including an intermediate interconnection structure may be disposed on a lower structure including an interconnection structure, and each of the above intermediate structures may include a plurality of insulating layers.

According to an aspect of the disclosure, a semiconductor device includes: a lower structure including a substrate, and a lower transistor on the substrate; an intermediate structure on the lower structure; and an upper structure on the intermediate structure, the upper structure including an upper transistor and a data storage structure, wherein the intermediate structure includes: an intermediate interlayer insulating layer on the lower structure; an intermediate interconnection structure including an intermediate plug and an intermediate interconnection portion on the intermediate plug, wherein the intermediate plug penetrates the intermediate interlayer insulating layer; an intermediate stopper layer including an intermediate stopper horizontal portion on the intermediate interlayer insulating layer, and an intermediate stopper extension portion extending from the intermediate stopper horizontal portion and covering a side surface and an upper surface of the intermediate interconnection portion; and an intermediate gap-fill insulating layer on an external side surface of the intermediate stopper extension portion and on the intermediate stopper horizontal portion of the intermediate stopper layer.

According to an aspect of the disclosure, a semiconductor device includes: a lower structure including a lower transistor; an intermediate structure on the lower structure; and an upper structure on the intermediate structure, the upper structure including a data storage structure, wherein the intermediate structure includes: a first intermediate interlayer insulating layer; a first intermediate interconnection structure penetrating the first intermediate interlayer insulating layer, the first intermediate interconnection structure including a first intermediate plug and a first intermediate interconnection portion on the first intermediate plug; a first intermediate stopper layer including a first horizontal portion on the first intermediate interlayer insulating layer, and a first extension portion extending from the first horizontal portion, wherein the first extension portion is on a side surface and an upper surface of the first intermediate interconnection structure; a first intermediate gap-fill insulating layer on an upper surface of the first horizontal portion and on an external side surface of the first extension portion; a second intermediate interlayer insulating layer on an upper surface of the first extension portion and on an upper surface of the first intermediate gap-fill insulating layer; and a second intermediate interconnection structure including a second intermediate plug and a second intermediate interconnection portion on the second intermediate plug, wherein the second intermediate plug penetrates the second intermediate interlayer insulating layer and the first extension portion and is connected to the first intermediate interconnection portion, wherein the first intermediate interlayer insulating layer, the first intermediate stopper layer, and the second intermediate interlayer insulating layer include an insulating nitride, and wherein the first intermediate gap-fill insulating layer includes an insulating oxide.

According to an aspect of the disclosure, a semiconductor device includes: a lower structure including a substrate; at least one intermediate structure on the lower structure; and an upper structure on the at least one intermediate structure, the upper structure including an upper transistor and a data storage structure on the upper transistor, wherein the lower structure includes: a peripheral transistor on the substrate, the peripheral transistor including a peripheral source/drain and a peripheral gate; a lower interlayer insulating layer on the substrate, wherein the lower interlayer insulating layer covers at least a side surface of the peripheral gate; a lower interconnection structure including a lower plug penetrating the lower interlayer insulating layer, and a lower interconnection portion on the lower plug; a lower stopper layer on the lower interlayer insulating layer and on the lower interconnection structure, the lower stopper layer including a lower stopper horizontal portion on the lower interlayer insulating layer, and a lower stopper extension portion extending from the lower stopper horizontal portion and covering a side surface and an upper surface of the lower interconnection portion; and a lower gap-fill insulating layer on the lower stopper extension portion, wherein the at least one intermediate structure includes: an intermediate interlayer insulating layer on the lower stopper extension portion and on the lower gap-fill insulating layer; an intermediate interconnection structure including an intermediate plug and an intermediate interconnection portion on the intermediate plug, wherein the intermediate plug penetrates the intermediate interlayer insulating layer and the lower stopper layer; an intermediate stopper layer on the intermediate interlayer insulating layer and on the intermediate interconnection structure, the intermediate stopper layer including an intermediate stopper horizontal portion on the intermediate interlayer insulating layer, and an intermediate stopper extension portion extending from the intermediate stopper horizontal portion and covering a side surface and an upper surface of the intermediate interconnection portion; and an intermediate gap-fill insulating layer on the intermediate stopper horizontal portion, wherein the upper structure includes: an upper interlayer insulating layer on the intermediate stopper extension portion and on the intermediate gap-fill insulating layer; an upper interconnection structure including a contact plug and a bitline on the contact plug, wherein the contact plug penetrates the upper interlayer insulating layer and is connected to the intermediate plug; and an upper stopper layer on the upper interlayer insulating layer and on the upper interconnection structure, and wherein the upper transistor includes: a vertical channel portion on the bitline; a wordline facing a side surface of the vertical channel portion; and a dielectric structure between the side surface of the vertical channel portion and the wordline.

### BRIEF DESCRIPTION OF DRAWINGS

The above and other aspects, features, and advantages in the example embodiment will be more clearly understood from the following detailed description, taken in combination with the accompanying drawings, in which:

FIG. 1 is a plan diagram illustrating a semiconductor device according to an example embodiment of the present disclosure;

FIG. 2A is a vertical cross-sectional diagram illustrating the semiconductor device illustrated in FIG. 1 taken along line I-I′;

FIG. 2B is an enlarged diagram illustrating a portion of the semiconductor device illustrated in FIG. 2A;

FIG. 3 is vertical cross-sectional diagram illustrating the semiconductor device illustrated in FIG. 1 taken along line II-II′;

FIGS. 4A, 4B and 4C are enlarged diagrams illustrating a portion of the semiconductor device according to an example embodiment of the present disclosure;

FIG. 5 is a vertical cross-sectional diagram illustrating the semiconductor device illustrated in FIG. 1 according to an example embodiment of the present disclosure;

FIGS. 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, 17B, 18A, 18B, 19A, 19B, 20A, 20B, 21A and 21B are vertical cross-sectional diagrams illustrating processes of a method of manufacturing a semiconductor device according to an example embodiment of the present disclosure; and

FIGS. 22A, 22B, 23A, 23B, 24A and 24B are vertical cross-sectional diagrams illustrating processes of a method of manufacturing a semiconductor device according to an example embodiment of the present disclosure.

### DETAILED DESCRIPTION

Hereinafter, embodiments in the example embodiment will be described as follows with reference to the accompanying drawings.

In the following description, like reference numerals refer to like elements throughout the specification. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

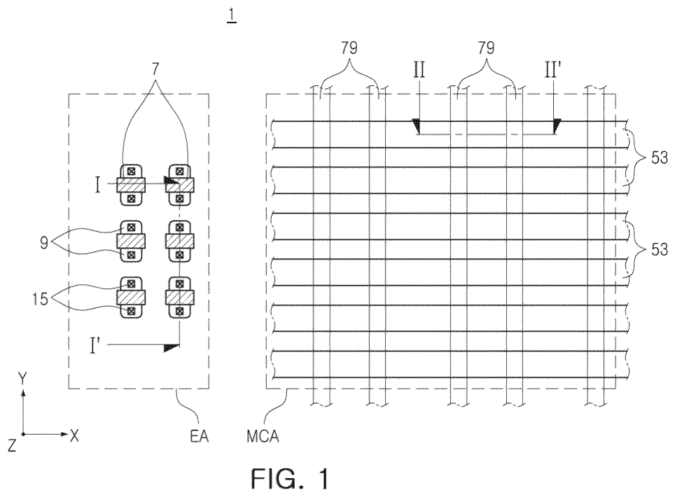

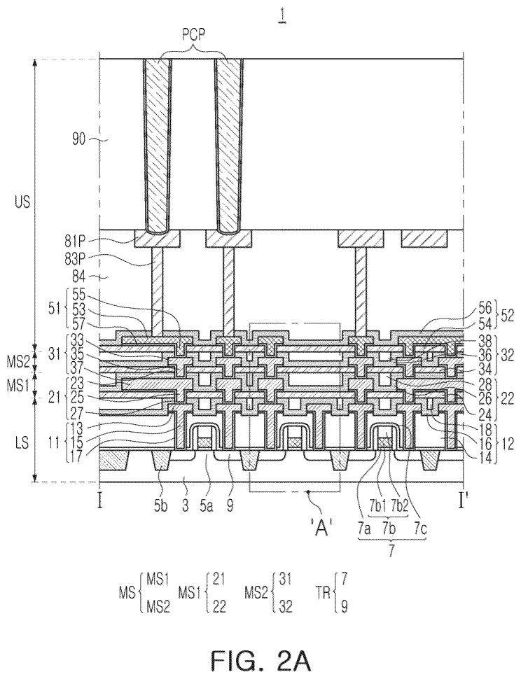

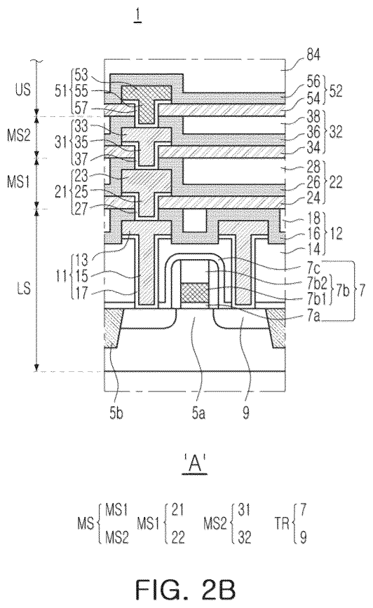

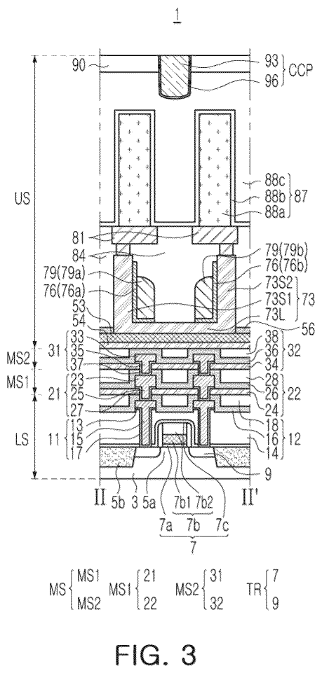

FIG. 1 is a plan diagram illustrating a semiconductor device according to an example embodiment. FIG. 2A is a vertical cross-sectional diagram illustrating the semiconductor device illustrated in FIG. 1 taken along line I-I′. FIG. 2B is an enlarged diagram illustrating a portion of the semiconductor device illustrated in FIG. 2A. FIG. 3 is vertical cross-sectional diagrams illustrating the semiconductor device illustrated in FIG. 1 taken along line II-II′.

Referring to FIGS. 1 to 3, a semiconductor device 1 according to an example embodiment may include a lower structure LS, an intermediate structure MS, and an upper structure US.

The lower structure LS may include a substrate 3 and a peripheral transistor TR (or “lower transistor”) disposed on the substrate 3. The peripheral transistor TR may include a wordline driver, a sense amplifier, row and column decoders and control circuits. The substrate 3 may include a cell array region MCA and a connection region EA.

The substrate 3 may include a semiconductor material, such as a group IV semiconductor, a group III-V compound semiconductor, or a group II-VI compound semiconductor. For example, a group IV semiconductors may include silicon, germanium, or silicon-germanium. The substrate 3 may be configured as a silicon substrate, silicon-on-insulator (SOI) substrate, germanium substrate, germanium-on-insulator (GOI) substrate, silicon-germanium substrate, or a substrate including an epitaxial layer.

The peripheral transistor TR may be disposed in the cell array region MCA and the connection region EA. The peripheral transistor TR may include a gate structure 7 disposed on a peripheral active region 5a defined by the device isolation region 5b in the substrate 3, and peripheral source/drain regions 9 disposed in the peripheral active region 5a on both sides of the gate structure 7.

The gate structure 7 may include a peripheral gate electrode 7b and a peripheral gate dielectric layer 7a between the peripheral gate electrode 7b and the peripheral active region 5a. The peripheral gate electrode 7b may include at least two conductive layers, for example, a first conductive layer 7b1 and a second conductive layer 7b2 on the first conductive layer 7b1. The gate structure 7 may further include an insulating liner 7c disposed on the substrate 3 and covering side surfaces of the peripheral gate dielectric layer 7a and the peripheral gate electrode 7b.

The lower structure LS may further include a lower interconnection structure 11 and a lower insulating structure 12. The lower interconnection structure 11 may include a peripheral interconnection portion 13 (also referred to herein as a lower interconnection portion 13) and a peripheral plug 15 (also referred to herein as lower plug 15), and the lower insulating structure 12 may include a lower interlayer insulating layer 14, a lower stopper layer 16, and a lower gap-fill insulating layer 18.

The peripheral plug 15 may be connected to the peripheral source/drain region 9 and may extend vertically, and the peripheral interconnection portion 13 may be disposed on the peripheral plug 15. The peripheral interconnection portion 13 may be electrically connected to the peripheral transistor TR through the peripheral plug 15. The peripheral interconnection portion 13 and the peripheral plug 15 may be configured as a metal layer including a metal material such as W or Mo.

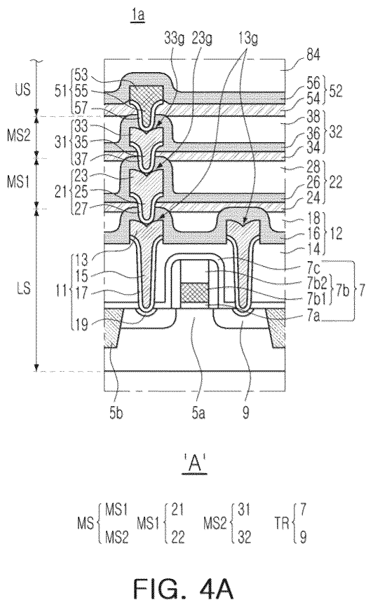

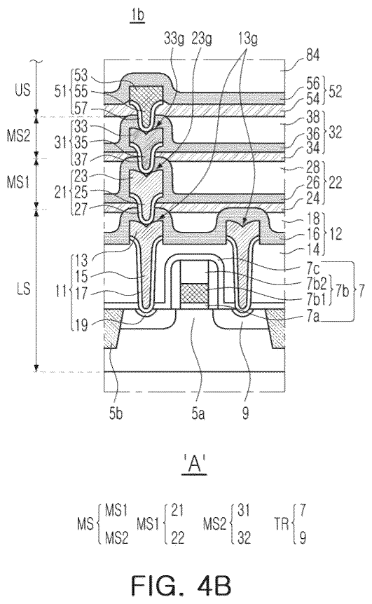

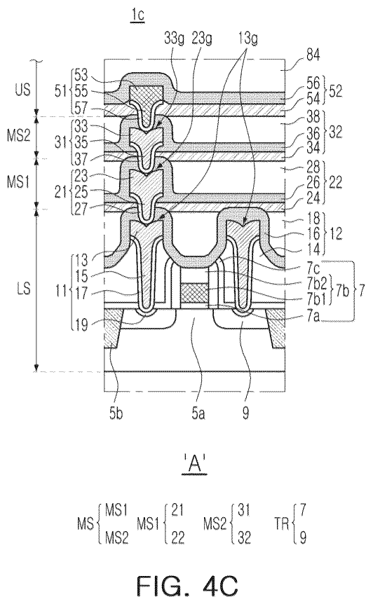

The lower interlayer insulating layer 14 may surround side surfaces of peripheral gate electrode 7b and the peripheral plug 15. The lower stopper layer 16 may include a lower stopper horizontal portion disposed on the lower interlayer insulating layer 14 and a lower stopper extension portion extending to cover a side surface and an upper surface of the peripheral interconnection portion 13. A level of the upper surface of the lower stopper extension portion may be higher level than a level of the upper surface of the lower stopper horizontal portion. A lower gap-fill insulating layer 18 may be disposed on the lower stopper layer 16. For example, the lower gap-fill insulating layer 18 may be disposed on the lower stopper horizontal portion of the lower stopper layer 16, and a side surface of the lower gap-fill insulating layer 18 may be disposed on a side surface of the lower stopper extension portion. An upper surface of the lower stopper extension portion and an upper surface of the lower gap-fill insulating layer 18 may be coplanar with each other. Alternatively, according to an example embodiment, the upper surface of the lower stopper extension portion may be on a level higher than a level of the upper surface of the lower gap-fill insulating layer 18 (see FIG. 4A).

The lower interlayer insulating layer 14 and the lower gap-fill insulating layer 18 may include a silicon oxide material, and the lower stopper layer 16 may include a silicon nitride material. For example, the silicon oxide material may include silicon oxide (SiO₂), and the silicon nitride material may include silicon nitride (SiN), silicon carbonitride (SiCN), or silicon boron nitride (SiBN), but the disclosure is not limited thereto.

The lower interconnection structure 11 may further include a barrier layer 17 covering a lower surface of the lower interconnection portion 13 and a side surface and lower surface of the lower plug 15. A portion of barrier layer 17 covering the lower surface of lower interconnection portion 13 may be in contact with the lower stopper layer 16. A portion of barrier layer 17 covering the side surface of the lower plug 15 may be in contact with lower interlayer insulating layer 14. The barrier layer 17 may include at least one of TiN, TaN, WN, TiSiN, TaSiN, or RuTiN.

The intermediate structure MS may be disposed on the lower structure LS. The intermediate structure MS may include the first intermediate structure MS1 and the second intermediate structure MS2.

The first intermediate structure MS1 may include the first intermediate interconnection structure 21 and the first intermediate insulating structure 22. The first intermediate interconnection structure 21 may include a first intermediate interconnection portion 23 and a first intermediate plug 25, and the first intermediate insulating structure 22 may include a first intermediate interlayer insulating layer 24, a first intermediate stopper layer 26, and a first intermediate gap-fill insulating layer 28.

The first intermediate plug 25 may penetrate the first intermediate interlayer insulating layer 24 and the lower stopper layer 16 may be in contact with an upper region of the lower interconnection portion 13. The first intermediate interconnection portion 23 may be disposed on the first intermediate plug 25. The first intermediate interconnection portion 23 may be electrically connected to the peripheral transistor TR through the first intermediate plug 25 and the lower interconnection structure 11. The first intermediate interconnection portion 23 and the first intermediate plug 25 may be configured as a metal layer including a metal material such as W or Mo.

The first intermediate interlayer insulating layer 24 may be disposed on the lower stopper layer 16 and the lower gap-fill insulating layer 18. For example, the first intermediate interlayer insulating layer 24 may be disposed to cover an upper surface of the lower stopper extension portion of the lower stopper layer 16 and an upper surface of the lower gap-fill insulating layer 18. The first intermediate stopper layer 26 may be disposed on the first intermediate interlayer insulating layer 24 and the first intermediate interconnection portion 23. For example, the first intermediate stopper layer 26 may include a first intermediate stopper horizontal portion disposed on the first intermediate interlayer insulating layer 24, and a first intermediate stopper extension portion covering a side surface and an upper surface of the first intermediate interconnection portion 23. The first intermediate gap-fill insulating layer 28 may be disposed on the first intermediate stopper layer 26. For example, the first intermediate gap-fill insulating layer 28 may be disposed on the first intermediate stopper horizontal portion of the first intermediate stopper layer 26, and a side surface of the first intermediate gap-fill insulating layer 28 may be in contact with the side surface of the first intermediate stopper extension portion. An upper surface of the first intermediate stopper extension portion and an upper surface of the first intermediate gap-fill insulating layer 28 may be coplanar with each other. Alternatively, according to an example embodiment, an upper surface of the first intermediate stopper extension portion may be disposed on a level higher than a level of an upper surface of the first intermediate gap-fill insulating layer 28 (see FIG. 4A).

The first intermediate interlayer insulating layer 24 and the first intermediate stopper layer 26 may include a material the same as or similar to that of the lower stopper layer 16. For example, the first intermediate interlayer insulating layer 24 and the first intermediate stopper layer 26 may include an insulating nitride (for example, the silicon nitride) material. The first intermediate gap-fill insulating layer 28 may include a material the same as or similar to that of the lower gap-fill insulating layer 18. For example, the first intermediate gap-fill insulating layer 28 may include an insulating oxide (for example, the silicon oxide) material.

The first intermediate interconnection structure 21 may further include a barrier layer 27 covering a lower surface of the first intermediate interconnection portion 23 and a side surface and lower surface of the first intermediate plug 25. A portion of the barrier layer 27 covering a lower surface of the first intermediate interconnection portion 23 may be in contact with the first intermediate stopper layer 26. A portion of the barrier layer 27 covering a side surface of the first intermediate plug 25 may be in contact with the intermediate gap-fill insulating layer 28 and the lower stopper layer 16. The barrier layer 27 may include a material the same as or similar to that of the barrier layer 17.

The second intermediate structure MS2 may be disposed on the first intermediate structure MS1. The second intermediate structure MS2 may include a second intermediate interconnection structure 31 and a second intermediate insulating structure 32. The second intermediate interconnection structure 31 may include a second intermediate interconnection portion 33 and a second intermediate plug 35, and the second intermediate insulating structure 32 may include a second intermediate interlayer insulating layer 34, a second intermediate stopper layer 36, and a second intermediate gap-fill insulating layer 38.

The second intermediate plug 35 may penetrate the second intermediate interlayer insulating layer 34 and the first intermediate stopper layer 26 and may be in contact with an upper region of the first intermediate interconnection portion 23. The second intermediate interconnection portion 33 may be disposed on the second intermediate plug 35. The second intermediate interconnection portion 33 may be electrically connected to the peripheral transistor TR through the second intermediate plug 35, the first intermediate interconnection structure 21, and the lower interconnection structure 11. The second intermediate interconnection portion 33 and the second intermediate plug 35 may be configured as a metal layer including a metal material such as W or Mo.

The second intermediate interlayer insulating layer 34 may be disposed on the first intermediate stopper layer 26 and the first intermediate gap-fill insulating layer 28. For example, the second intermediate interlayer insulating layer 34 may be disposed to cover an upper surface of the first intermediate stopper extension portion of the first intermediate stopper layer 26 and an upper surface of the first intermediate gap-fill insulating layer 28. The second intermediate stopper layer 36 may be disposed on the second intermediate interlayer insulating layer 34 and the second intermediate interconnection portion 33. For example, the second intermediate stopper layer 36 may include a second intermediate stopper horizontal portion disposed on the second intermediate interlayer insulating layer 34, and a second intermediate stopper extension portion covering a side surface and an upper surface of the second intermediate interconnection portion 33. The second intermediate gap-fill insulating layer 38 may be disposed on the second intermediate stopper layer 36. For example, the second intermediate gap-fill insulating layer 38 may be disposed on the second intermediate stopper horizontal portion of the second intermediate stopper layer 36, and a side surface of the second intermediate gap-fill insulating layer 38 may be in contact with a side surface of the second intermediate stopper extension portion. An upper surface of the second intermediate stopper extension portion and an upper surface of the second intermediate gap-fill insulating layer 38 may be coplanar with each other. Alternatively, according to an example embodiment, an upper surface of the second intermediate stopper extension portion may be disposed on a level higher than a level of an upper surface of the second intermediate gap-fill insulating layer 38 (see FIG. 4A).

The second intermediate interlayer insulating layer 34 and the second intermediate stopper layer 36 may include a material the same as or similar to that of the first intermediate interlayer insulating layer 24 and the first intermediate stopper layer 26. For example, the second intermediate interlayer insulating layer 34 and the second intermediate stopper layer 36 may include the silicon nitride material. The second intermediate gap-fill insulating layer 38 may include a material the same as or similar to that of the first intermediate gap-fill insulating layer 28. For example, the second intermediate gap-fill insulating layer 38 may include the silicon oxide material.

The second intermediate interconnection structure 31 may further include a barrier layer 37 covering a lower surface of the second intermediate interconnection portion 33 and a side surface and a lower surface of the second intermediate plug 35. A portion of barrier layer 37 covering the lower surface of the second intermediate interconnection portion 33 may be in contact with the second intermediate stopper layer 36. A portion of the barrier layer 37 covering a side surface of the second intermediate plug 35 may be in contact with the intermediate gap-fill insulating layer 28 and the first intermediate stopper layer 26. The barrier layer 37 may include a material the same as or similar to that of barrier layer 27.

Thicknesses of the lower interconnection portion 13 and the first and second intermediate interconnection portions 23 and 33 may be different. For example, the thickness of the second intermediate interconnection portion 33 may be greater than the thicknesses of the lower interconnection portion 13 and the first intermediate interconnection portion 23. Accordingly, a level of resistance of the interconnection portions 13, 23, and 33 or a level of current flowing through the interconnection portions 13, 23, and 33 may be adjusted. However, the thickness between the interconnection portions 13, 23, 33 and the bitline 53 is not limited to an example embodiment illustrated in FIGS. 2A, 2B, and 3, and may be varied.

In other words, by disposing at least one intermediate structure including an intermediate interconnection structure on a lower structure including an interconnection structure, various interconnection structures may be implemented, thereby increasing flexibility in design.

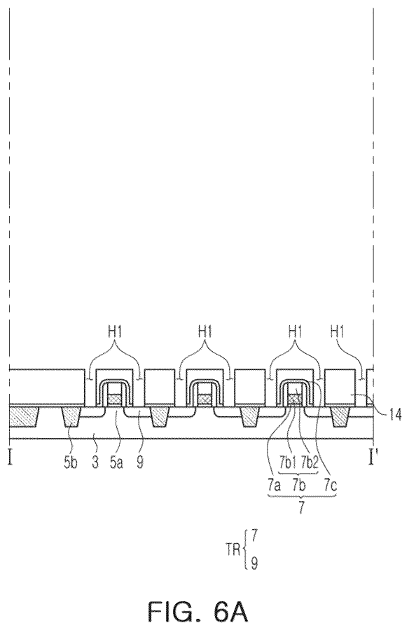

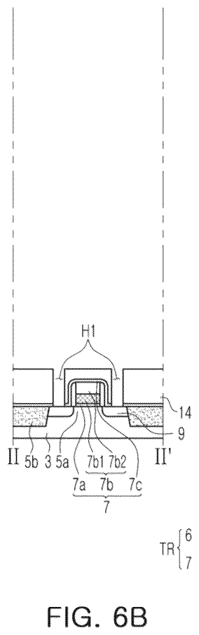

Also, as each of the intermediate structures includes an insulating structure including a plurality of insulating layers, a level of warpage occurring in the other processes in FIGS. 6A to 21B may be alleviated.

The upper structure US may be disposed on the intermediate structure MS. The upper structure US may include an upper interconnection structure 51 and an upper insulating structure 52. The upper interconnection structure 51 may include a bitline 53 and a contact plug 55, and the upper insulating structure 52 may include an upper interlayer insulating layer 54 and an upper stopper layer 56. The upper interconnection structure 51 may further include a barrier layer 57 covering a lower surface of the bitline 53 and a side surface and a lower surface of the contact plug 55. The barrier layer 57 may include a material the same as or similar to that of barrier layers 27 and 37.

The contact plug 55 may penetrate the upper interlayer insulating layer 54 and the second intermediate stopper layer 36 and may be in contact with an upper region of the second intermediate interconnection portion 33. The bitline 53 may be disposed on the contact plug 55. The bitlines 53 may extend in the first horizontal direction X and may be spaced apart from each other in the second horizontal direction Y The first horizontal direction X and the second horizontal direction Y may be perpendicular to each other. The bitline 53 may be electrically connected to the peripheral transistor TR through the contact plug 55, the first and second intermediate interconnection structure 21 and 31, and the lower interconnection structure 11. The bitline 53 may include doped polysilicon, a metal, conductive metal nitride, a metal-semiconductor compound, a metal compound, conductive metal oxide, graphene, carbon nanotube, or a combination thereof.

The semiconductor device 1 in the cell array region MCA may further include shield patterns extending in the first horizontal direction X and spaced apart from each other in the second horizontal direction Y The shield patterns may be disposed alternately with the bitlines 53 in the second horizontal direction Y The shield patterns may reduce capacitance between the bitlines 53.

The upper interlayer insulating layer 54 may be disposed on the second intermediate stopper layer 36 and the second intermediate gap-fill insulating layer 38. For example, the upper interlayer insulating layer 54 may be disposed to cover an upper surface of the second intermediate stopper extension portion of the second intermediate stopper layer 36 and an upper surface of the second intermediate gap-fill insulating layer 38. The upper stopper layer 56 may be disposed on the upper interlayer insulating layer 54 and the bitline 53. For example, the upper stopper layer 56 may include an upper stopper horizontal portion disposed on the upper interlayer insulating layer 54, and an upper stopper extension portion covering an upper surface and a side surface of the bitline 53.

The upper structure US may further include a channel structure 73, wordlines 79, an upper gap-fill insulating layer 84, an upper interconnection 81p and an upper plug 83p disposed on the bitline 53.

The channel structure 73 may be disposed on the bitline 53. The channel structure 73 may include a horizontal portion 73L in contact with and electrically connected to the bitline 53, and a first vertical channel portion 73S1 and a second vertical channel portion 73S2 extending in the vertical direction Z on both sides of the horizontal portion 73L in the horizontal direction. The vertical direction Z may be perpendicular to an upper surface of the substrate 3.

The channel structure 73 may be formed of a semiconductor material such as silicon. The channel structure 73 may be formed of single crystal silicon or polysilicon. However, the channel structure 73 is not limited to a semiconductor material such as silicon, and may be formed of another semiconductor material used as a channel region of a transistor. For example, the channel structure 73 may include an oxide semiconductor layer or a two-dimensional material layer used as a channel region of a transistor. Here, the transistor may be referred to as an upper transistor, disposed on a level higher than a level of the lower transistor TR.

The oxide semiconductor layer may be indium gallium zinc oxide (IGZO). However, the disclosure is not limited thereto. For example, the oxide semiconductor layer may include at least one of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO).

The two-dimensional material layer may include at least one of a transition metal dichalcogenide material layer (TMD material layer), a black phosphorous material layer and a hexagonal boron-nitride material layer (hBN material layer) which may have semiconductor properties. For example, the two-dimensional material layer may include at least one of BiOSe, Crl, WSe2, MoS2, TaS, WS, SnSe, ReS, β-SnTe, MnO, AsS, P(black), InSe, h-BN, GaSe, GaN, SrTiO, MXene, and Janus 2D material (Janus 2D materials), which may form a two-dimensional material.

Each of the wordlines 79 may extend in the second horizontal direction Y A pair of wordlines 79a and 79b of the wordlines 79 may vertically overlap the horizontal portion 73L of the channel structure 73 and may be disposed between the first and second vertical channel portions 73S1 and 73S2 of the channel structure 73. The pair of wordlines 79a and 79b may include a first wordline 79a facing the first vertical channel portion 73S1 and a second wordline 79b facing the second vertical channel portion 73S2.

The upper structure US may further include dielectric structures 76 between the wordlines 79 and the channel structure 73. The dielectric structures 76 may include a first dielectric structure 76a disposed between the first wordline 79a and the first vertical channel portion 73S1, and between the first wordline 79a and the horizontal portion 73L, and a second dielectric structure 76b disposed between the second wordline 79b and the second vertical channel portion 73S2, and between the second wordline 79b and the horizontal portion 73L.

In an example, each of the dielectric structures 76 may be configured as a tunnel dielectric layer not including a data storage layer. For example, each of the dielectric structures 76 may include at least one of silicon oxide and high-x dielectric. The high-x dielectric may include metal oxide or metal oxynitride. For example, the high-x dielectric may be formed of HfSiO, HfSiON, HfTaO, HfTiO, HfZrO, ZrO₂, Al₂O₃, or a combination thereof, but the disclosure is not limited thereto. Each of the dielectric structures 76 may include a single layer or multiple layers formed of the materials mentioned above.

In another example, each of the dielectric structures 76 may include a data storage layer and a dielectric layer. For example, each of the dielectric structures 76 may have polarization properties depending on an electric field and may include a ferroelectric layer which may have remnant polarization by dipoles even in the absence of an external electric field. Data may be written using the polarization state in the ferroelectric layer. Accordingly, each of the dielectric structures 76 may include a ferroelectric layer, which may be referred to as a data storage layer. The ferroelectric layer, which may be configured as the data storage layer, may include an Hf-based compound, a Zr-based compound, and/or an Hf—Zr-based compound. For example, the Hf-based compound may include a HfO-based ferroelectric material, the Zr-based compound may include a ZrO-based ferroelectric material, and the Hf—Zr-based compound may include a hafnium zirconium oxide (HZO) ferroelectric material. The ferroelectric layer, which may be configured as the data storage layer, may include a ferroelectric material doped with impurities, such as at least one of C, Si, Mg, Al, Y, N, Ge and Sn, Gd, La, Sc and Sr. For example, the ferroelectric layer, which may be the data storage layer, may be a material formed by at least one of HfO₂, ZrO₂ and HZrO doped with at least one of C, Si, Mg, Al, Y, N, Ge, Sn, Gd, La, Sc and Sr.

In the dielectric structures 76, the data storage layer is not limited to the above-mentioned materials and may include a material which may store data.

The upper structure US may further include landing pads 81 in contact with and electrically connected to the first and second vertical channel portions 73S1 and 73S2, respectively, on the channel structure 73. The landing pads 81 may be formed of a conductive material.

The upper gap-fill insulating layer 84 may be disposed on the bitlines 53 and the upper stopper layer 56. The upper gap-fill insulating layer 84 may cover a side surface of the upper interconnection 81p and the upper plug 83p in the connection region EA. The upper gap-fill insulating layer 84 may cover a side surface of a structure including the channel structure 73, the wordlines 79, and the landing pads 81 in the cell array region MCA.

The upper interconnection 81p may be disposed on the same level as the landing pads 81 in the connection region EA. For example, an upper surface of the upper interconnection 81p may be disposed on the same level as an upper surface of the landing pads 81. The upper plug 83p may extend in the vertical direction Z, and one of the upper interconnections 81p may be connected to the bitline 53. The upper interconnection 81p may include the same material as the landing pads 81. The upper gap-fill insulating layer 84 may surround a side surface of the upper interconnection 81p and the upper plug 83p in the connection region EA. The upper gap-fill insulating layer 84 may include silicon oxide, silicon nitride, silicon oxynitride, low-k dielectric, or a combination thereof. For example, the upper gap-fill insulating layer 84 may include silicon oxide.

The upper structure US may further include a data storage structure 87 disposed on the upper gap-fill insulating layer 84 and the landing pad 81. The data storage structure 87 may include first electrodes 88a electrically connected to and in contact with the landing pads 81, a second electrode 88c on the first electrodes 88a, and a dielectric layer 88b between the first electrodes 88a and the second electrode 88c.

In an example, the data storage structure 87 may be configured as a capacitor storing data in a DRAM. For example, the dielectric layer 88b of the data storage structure 87 may be configured as a capacitor dielectric layer of a DRAM, and the dielectric layer 88b may include high-x dielectric, silicon oxide, silicon nitride, silicon oxynitride, or a combination thereof.

In another example, the data storage structure 87 may be configured to store data in a memory other than a DRAM. For example, the data storage structure 87 may be configured to a capacitor of a ferroelectric memory (FeRAM). For example, the dielectric layer 88b may be configured to a ferroelectric layer which may write data using a polarization state. In another example, the dielectric layer 88b may include a lower dielectric layer and a ferroelectric layer on the lower dielectric layer. Here, the lower dielectric layer may include at least one of silicon oxide, silicon oxynitride, silicon nitride, and high-x dielectric (high-k dielectric).

In an example embodiment, when the dielectric structures 76 include a data storage layer, the data storage structure 87 may not be provided.

The upper structure US may further include an upper insulating structure 90. The upper insulating structure 90 may cover the data storage structure 87 in the cell array region MCA and the upper interconnection 81p in the connection region EA. The upper insulating structure 90 may include silicon oxide, silicon nitride, silicon oxynitride, low dielectric material, or a combination thereof. For example, the upper insulating structure 90 may include silicon oxide.

The upper structure US may further include a cell contact plug CCP extending in the vertical direction Z from the cell array region MCA, penetrating the upper insulating structure 90, and in contact with the data storage structure 87. For example, the cell contact plug CCP may be in contact with the second electrode 88c.

The upper structure US may further include a peripheral contact plug PCP extending in the vertical direction Z from the connection region EA, penetrating the upper insulating structure 90, and connected to at least a portion of the upper interconnections 81p. For example, the peripheral contact plug PCP may be in contact with an upper region of the at least a portion of the upper interconnections 81p.

In an example embodiment, the cell contact plug CCP and the peripheral contact plug PCP may be formed simultaneously and may include the same material. For example, each of the cell contact plug CCP and the peripheral contact plug PCP may include a metal layer 93 and a barrier layer 96 covering a lower surface and a side surface of the metal layer 93. The metal layer 93 may include a conductive material such as tungsten, and the barrier layer 96 may include a conductive material such as TiN. Upper surfaces of the cell contact plug CCP and the peripheral contact plug PCP may be coplanar with an upper surface of the upper insulating structure 90. The cell contact plug CCP and the peripheral contact plug PCP may have a tapered shape having a horizontal width decreasing downwardly.

Aback end of line (BEOL) interconnection structure may be disposed on the upper insulating structure 90, and at least a portion of the cell contact plugs CCP and the peripheral contact plugs PCP may be electrically connected to each other by the BEOL interconnection structure. The arrangement structure and the number of intermediate interconnection structures 21 and 31, and the peripheral contact plugs PCP illustrated in FIG. 2A, are merely examples, and the disclosure is not limited thereto. In some example embodiments, one or three or more intermediate interconnection structures may be disposed.

FIGS. 4A to 4C are enlarged diagrams illustrating a portion of the semiconductor device according to an example embodiment.

Referring to FIG. 4A, a semiconductor device 1a may be configured the same as or similar to the example described with reference to FIGS. 1 to 3, other than the configuration in which an upper surface of at least a portion of the lower and intermediate interconnection portions 13, 23, and 33 may have a groove portion.

Referring to FIG. 4A, the upper surface of the lower interconnection portion 13 may have the groove portion 13g. For example, the groove portion 13g may be deeper from both ends of the upper surface toward a center of the upper surface. Accordingly, the thickness of lower interconnection portion 13 may be inconsistent. For example, a thickness of the lower interconnection portion 13 may reduce from both ends of the lower interconnection portion 13 toward a center of the lower interconnection portion 13. In an embodiment, the lower interconnection portion 13 may be concave downwardly.

Upper surfaces of the first and second intermediate interconnection portions 23 and 33 may also have groove portions 23g and 33g (i.e., may be concave downwardly), respectively. When a vertical thickness of the interconnection portion is formed to be relatively thick, the groove portion may be formed to have a relatively reduced depth. For example, when the thickness of the second intermediate interconnection portion 33 is greater than the thickness of the first intermediate interconnection portion 23, the groove portion 33g of the second intermediate interconnection portion 33 is formed to have a relatively reduced length than that of the groove portion 23g of the first intermediate interconnection portion 23.

An upper surface of the bitline 53 of the upper structure US may have a flat surface.

Referring to FIG. 4A, each of the plurality of plugs 15, 25, 35 and the contact plug 55 may have an inclined side surface such that a width of each lower region thereof may be smaller than a width of the upper region.

Also, each of the lower interconnection portion 13, and the first and second intermediate interconnection portions 23 and 33 may have an inclined side surface. For example, the lower interconnection portion 13 may have an inclined side surface such that a width of the lower region may be greater than a width of the upper region, and or alternatively, the lower interconnection portion 13 may have an inclined side surface such that a width of the upper region may be smaller than a width of the lower region. Since a side surface of each of the first and second intermediate interconnection portions 23 and 33 may also be configured the same as or similar to the shape of the side surface of the lower interconnection portion 13, detailed descriptions thereof will not be provided.

Referring to FIG. 4A, upper surfaces of the extension portion of each of the lower and intermediate stopper layers 16, 26, and 36 may be disposed on a level higher than a level of upper surfaces of each of the lower and intermediate gap-fill insulating layers 18, 28, and 38. For example, an upper surface of the extension portion of the lower stopper layer 16 may not have a flat surface, and may have a curved shape in the vertical direction (Z direction). Accordingly, an upper surface of the extension portion of the lower stopper layer 16 may not be coplanar with an upper surface of the lower gap-fill insulating layer 18. Accordingly, the upper region of the extension portion of lower stopper layer 16 may be inserted into the lower region of the first intermediate interlayer insulating layer 24.

Referring to FIG. 4A, lower surfaces of each of the first and second intermediate stopper layers 26 and 36, and the upper stopper layer 56 may be disposed on a level lower than a level of lower surfaces of the first and second intermediate interconnection portions 23, 33 and the bitline 53.

Referring to FIG. 4A, the lower interconnection structure 11 may further include a metal-semiconductor compound layer 19 below the lower region of the barrier layer 17. The metal-semiconductor compound layer 19 may include at least one of metal silicide, such as WSi, TiSi, TaSi, NiSi and CoSi.

Referring to FIG. 4B, the semiconductor device 1b may be configured the same as or similar to the configuration in which film quality of one of the intermediate interconnection portions 23 and 33 may be different from film quality of the other.

Referring to FIG. 4B, an interconnection portion of one of the first and second intermediate interconnection portions 23 and 33 may have film quality denser than that of the other interconnection portions. For example, the film quality of the second intermediate interconnection portion 33 may be denser than that of the first intermediate interconnection portion 23. In this case, resistance of the second intermediate interconnection portion 33 may be smaller than resistance of the first intermediate interconnection portion 23.

Referring to FIG. 4C, semiconductor device 1c may be configured the same as or similar to the example described with reference to FIGS. 1 to 4B other than the configuration in which the lower stopper layer 16 may be in contact with at least a portion of the lower transistor TR.

Referring to FIG. 4C, a lower surface of lower stopper layer 16 may be in contact with an upper region of the lower transistor TR. For example, the lower stopper layer 16 may be disposed to be in contact with the second conductive layer 7b2 and the first insulating liner 7c of the lower transistor TR.

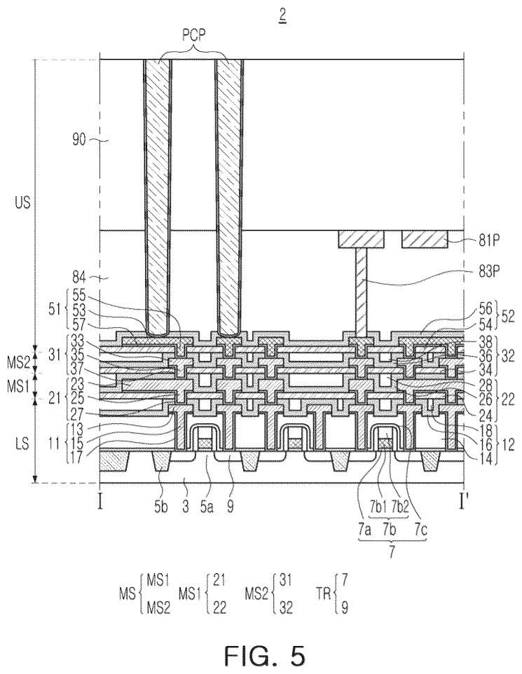

FIG. 5 is a vertical cross-sectional diagram illustrating the semiconductor device illustrated in FIG. 1 according to an example embodiment.

Referring to FIG. 5, a semiconductor device 2 may be configured the same as or similar to the example described with reference to FIGS. 1 to 4C other than the configuration in which the peripheral contact plug PCP may be in direct contact with the bitline 53 in the connection region EA.

Referring to FIG. 5, the peripheral contact plug PCP may penetrate an upper insulating structure 90, an upper gap-fill insulating layer 84 and an upper stopper layer 56 and may be in direct contact with the bitline 53. In other words, the peripheral contact plug PCP may not be electrically connected to the peripheral transistor TR through an upper interconnection 81p and an upper plug 83p.

FIGS. 6A to 21B are vertical cross-sectional diagrams illustrating processes of a method of manufacturing a semiconductor device in order according to an example embodiment.

FIGS. 6A to 8B are vertical cross-sectional diagrams illustrating processes of forming the lower interconnection structure 11 in order.

Referring to FIGS. 6A and 6B, a lower interlayer insulating layer 14 covering a peripheral transistor TR may be formed on a substrate 3. The lower interlayer insulating layer 14 may include a silicon oxide material. In the example embodiment, the lower interlayer insulating layer 14 may include silicon oxide (SiO₂).

Thereafter, a plurality of holes H1 penetrating the lower interlayer insulating layer 14 and exposing an upper surface of source/drain region 9 may be formed.

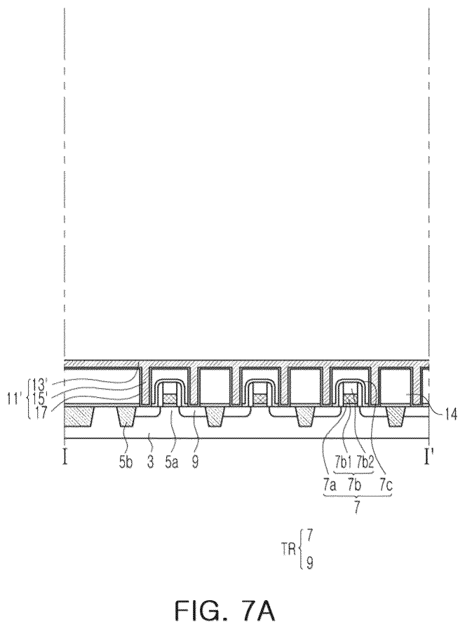

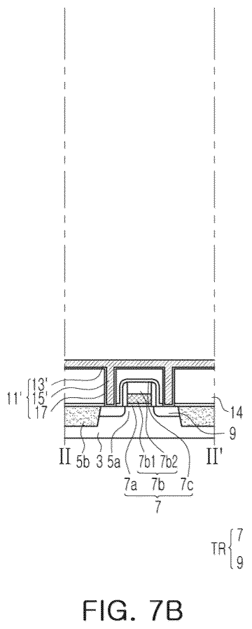

Referring to FIGS. 7A and 7B, a preliminary lower interconnection structure 11′ may be formed on the lower interlayer insulating layer 14.

The forming the preliminary lower interconnection structure 11′ may include forming a barrier layer 17 and depositing a conductive material on the barrier layer 17. The conductive material may be deposited by chemical vapor deposition (CVD).

For example, a barrier layer 17 conformally covering a surface of the plurality of holes H1 and an upper surface of the lower interlayer insulating layer 14 may be formed. Thereafter, a preliminary lower interconnection portion 13′ and a preliminary lower plug 15′ may be formed by depositing a conductive material on the barrier layer 17. The preliminary lower plug 15′ may fill the plurality of holes H1.

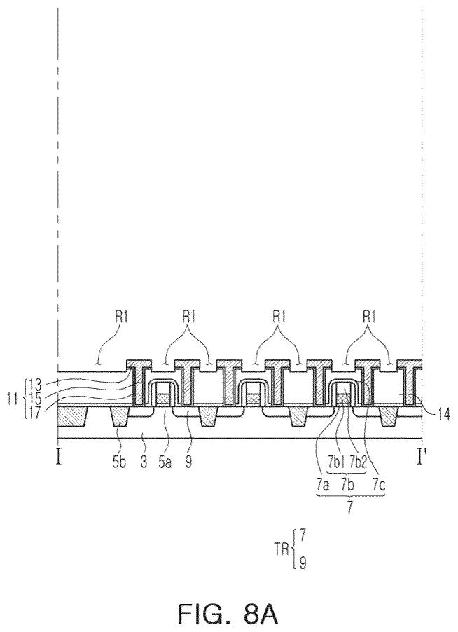

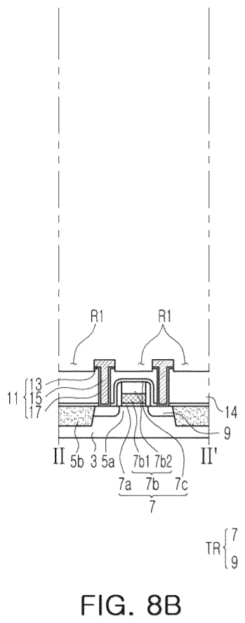

Referring to FIGS. 8A and 8B, the lower interconnection structure 11 may be formed.

The forming the lower interconnection structure 11 may include patterning the preliminary lower interconnection structure 11′. The patterning may include forming a mask pattern on the preliminary lower interconnection structure 11′ and forming recess regions R1 exposing an upper surface of the lower interlayer insulating layer 14 through an etching process. The lower surface of recess region R1 may be formed on a level lower than a level of the lower surface of barrier layer 17. Accordingly, the lower interconnection portion 13 and the lower plug 15 may be formed.

According to an example embodiment, the upper region of the peripheral transistor TR may be exposed by the etching process (see FIG. 5). Accordingly, at least a portion of the insulating liner 7c and the second conductive layer 7b2 of the peripheral transistor TR may be exposed.

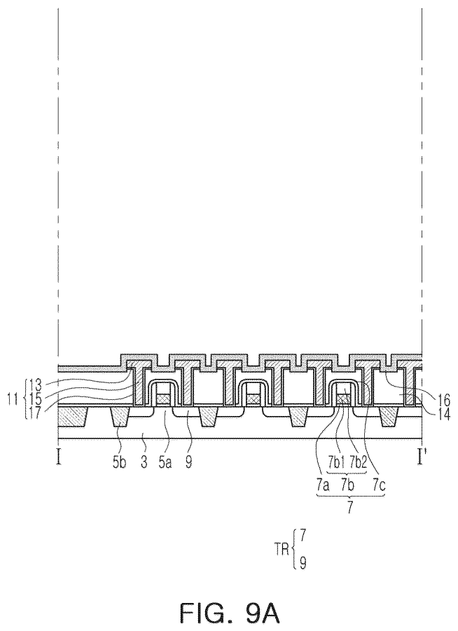

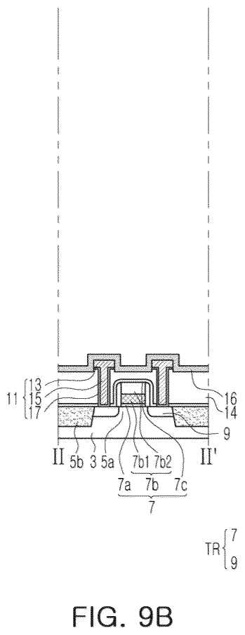

FIGS. 9A to 15B are process diagrams illustrating processes indicating a first cycle for forming the first intermediate interconnection structure 21 after the processes in FIGS. 8A and 8B.

Referring to FIGS. 9A and 9B, lower stopper layer 16 may be formed.

The lower stopper layer 16 may be formed to have a horizontal portion covering a surface of the lower interlayer insulating layer 14 exposed by the recess regions R1, and an extension portion covering a side surface of the barrier layer 17 and a side surface and an upper surface of the lower interconnection portion 13. The lower stopper layer 16 may work as an etch stop film. The lower stopper layer 16 may include a silicon nitride material. In the example embodiment, the lower stopper layer 16 may include silicon nitride (SiN).

According to an example embodiment, the lower stopper layer 16 may be formed to be in contact with the upper region of the peripheral transistor TR (see FIG. 5) in at least a portion of the recess regions R1. For example, the lower stopper layer 16 may be formed to be in contact with the insulating liner 7c and the second conductive layer 7b2 of the peripheral transistor TR.

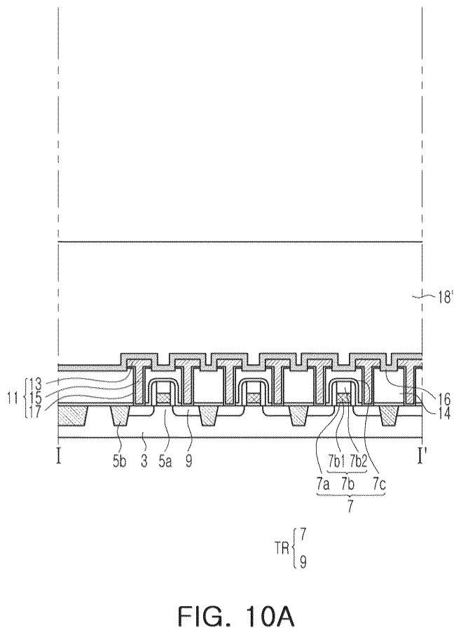

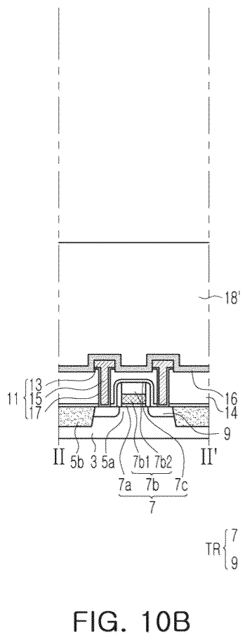

Referring to FIGS. 10A and 10B, a preliminary lower gap-fill insulating layer 18′ may be formed on the lower stopper layer 16.

The preliminary lower gap-fill insulating layer 18′ may include a silicon oxide material. In the example embodiment, the preliminary lower gap-fill insulating layer 18′ may include silicon oxide (SiO₂).

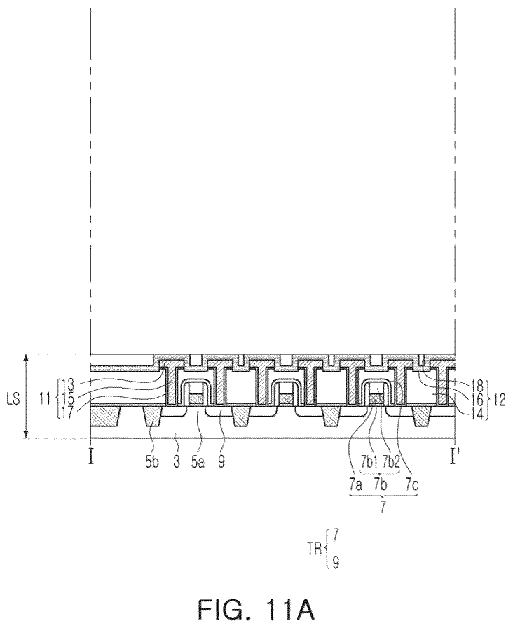

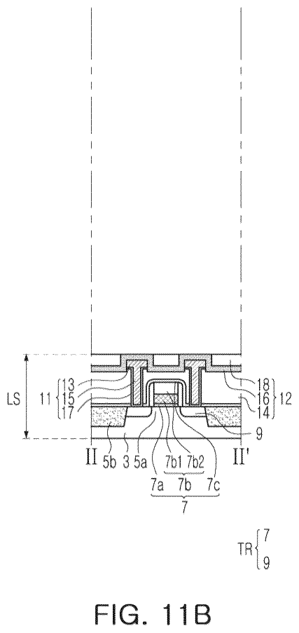

Referring to FIGS. 11A and 11B, a lower gap-fill insulating layer 18 may be formed.

The lower gap-fill insulating layer 18 may be formed through a planarization process such as chemical mechanical polishing (CMP) on the preliminary lower gap-fill insulating layer 18′ according to FIGS. 10A and 10B. Accordingly, an upper surface of the extension portion of lower stopper layer 16 may be exposed, and a lower gap-fill insulating layer 18 having an upper surface on the same level as an upper surface of lower stopper layer 16 may be formed.

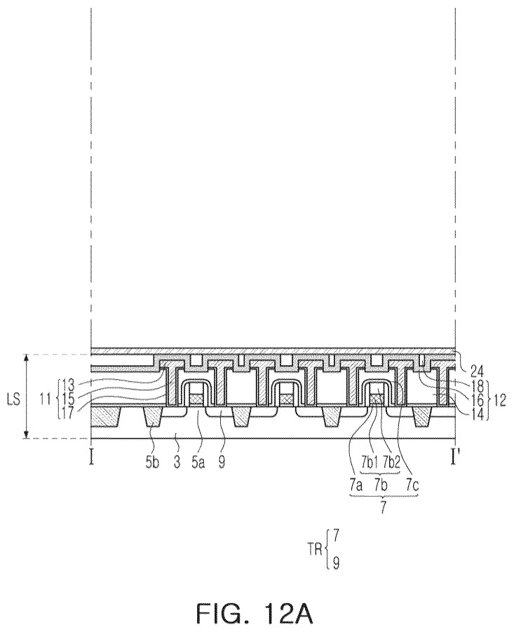

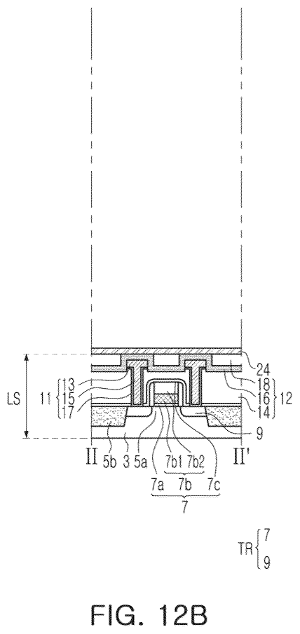

Referring to FIGS. 12A and 12B, the first intermediate interlayer insulating layer 24 may be formed on the lower gap-fill insulating layer 18 and the lower stopper layer 16.

The first intermediate interlayer insulating layer 24 may be deposited on an upper surface of the lower gap-fill insulating layer 18 and an upper surface of the extension portion of the lower stopper layer 16. The first intermediate interlayer insulating layer 24 may include a silicon nitride material. In the example embodiment, the first intermediate interlayer insulating layer 24 may include a silicon nitride material different from that of the lower stopper layer 16, and even when the first intermediate interlayer insulating layer 24 include the same material, a boundary therebetween may be distinct by a difference in physical properties.

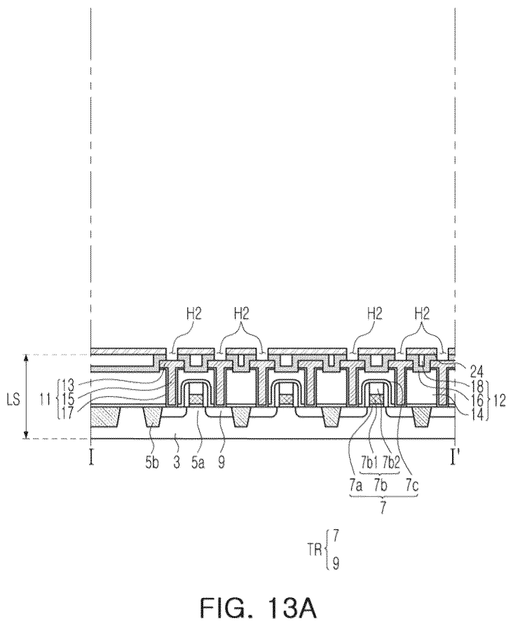

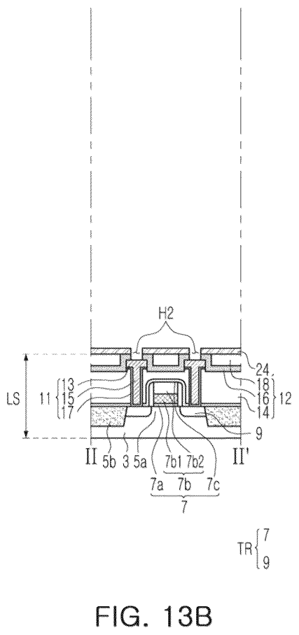

Referring to FIGS. 13A and 13B, a plurality of holes H2 penetrating the first intermediate interlayer insulating layer 24 and the lower stopper layer 16 and exposing an upper surface of the lower interconnection portion 13 may be formed.

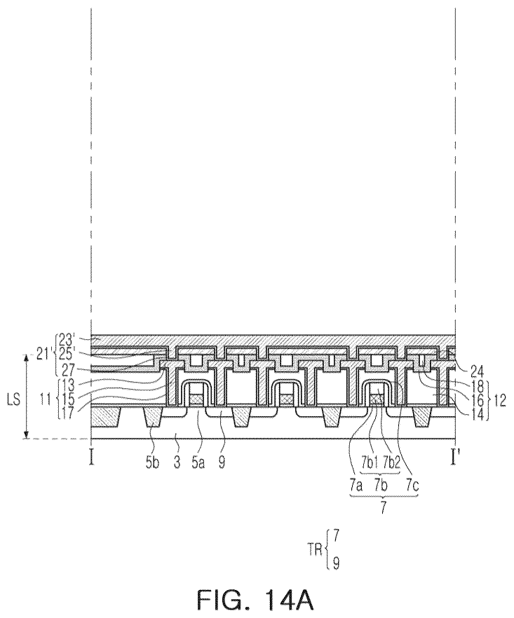

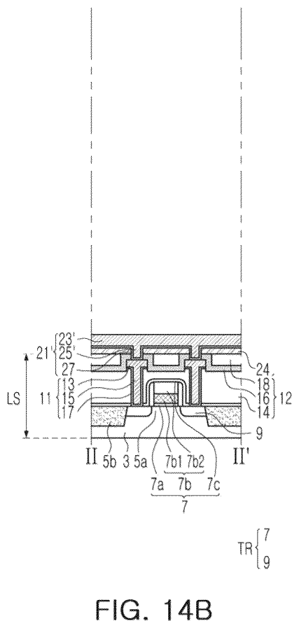

Referring to FIGS. 14A and 14B, a first preliminary intermediate interconnection structure 21′ may be formed on the first intermediate interlayer insulating layer 24.

The forming the first preliminary intermediate interconnection structure 21′ may be configured the same as or similar to the forming the preliminary lower interconnection structure 11′ described with reference to FIGS. 7A and 7B.

For example, the forming the first preliminary intermediate interconnection structure 21′ may include forming a barrier layer 27 and depositing a conductive material on the barrier layer 27. The conductive material may be deposited by chemical vapor deposition (CVD).

Specifically, a barrier layer 27 conformally covering a surface of a plurality of holes H2 and an upper surface of the first intermediate interlayer insulating layer 24 may be formed. Thereafter, a first preliminary intermediate interconnection portion 23′ and a first preliminary intermediate plug 25′ may be formed by depositing a conductive material on the barrier layer 27. The first preliminary intermediate plug 25′ may be a portion filling the plurality of holes H2.

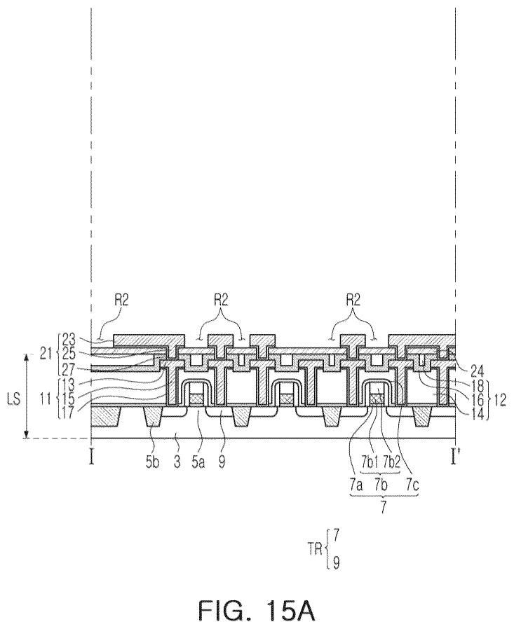

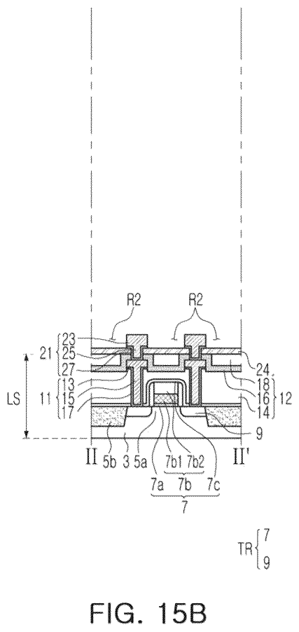

Referring to FIGS. 15A and 15B, the first intermediate interconnection structure 21 may be formed.

The forming the first intermediate interconnection structure 21 may be the same as or similar to the forming the lower interconnection structure 11 described with reference to FIGS. 8A and 8B.

For example, the forming the first intermediate interconnection structure 21 may include patterning the first preliminary intermediate interconnection structure 21′. The patterning may include forming a mask pattern on the first preliminary intermediate interconnection structure 21′ and forming a recess regions R2 exposing an upper surface of the first intermediate interlayer insulating layer 24 through an etching process. Accordingly, the first intermediate interconnection portion 23 and the first intermediate plug 25 may be formed.

As described above, the processes for forming the first intermediate interconnection structure 21 described with reference to FIGS. 9A to 15B may be referred to as “first cycle.”

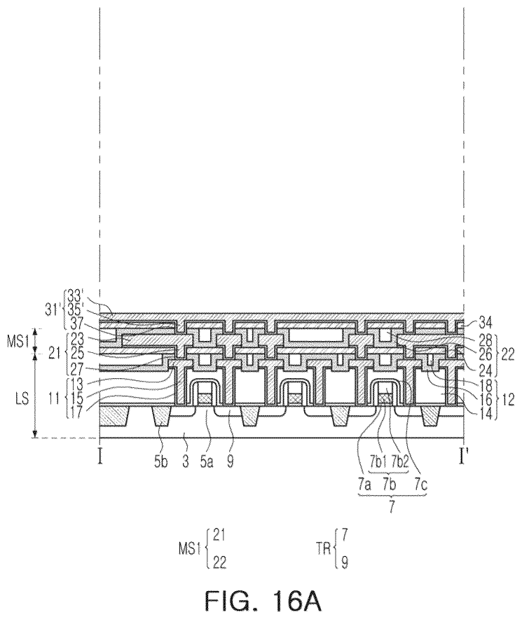

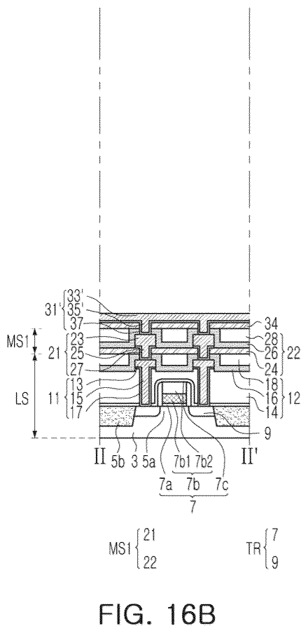

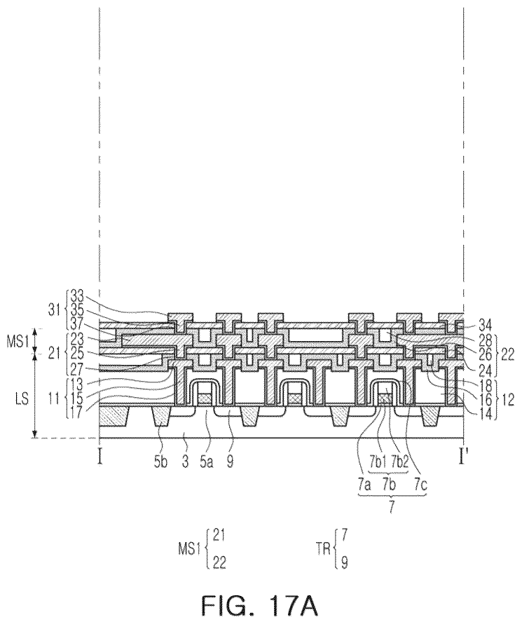

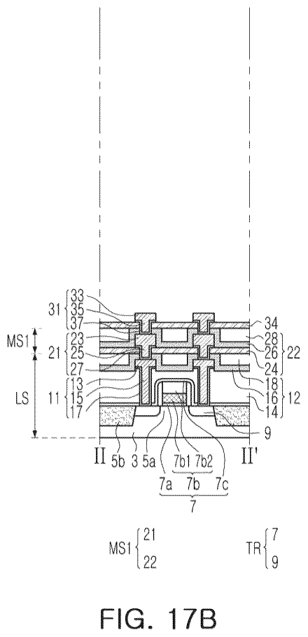

FIGS. 16A to 17B are process diagrams illustrating processes of a second cycle for forming a second intermediate interconnection structure 31 after the processes in FIGS. 15A and 15B. The second cycle may include processes the same as or similar to those of the first cycle described with reference to FIGS. 9A to 15B.

Referring to FIGS. 16A and 16B, a second preliminary intermediate interconnection structure 31′ may be formed on the first intermediate interconnection structure 21.

Similarly to the example described with reference to FIGS. 9A to 12B, a first intermediate stopper layer 26 covering the first intermediate interlayer insulating layer 24 and the first intermediate interconnection portion 23, a first intermediate gap-fill insulating layer 28 on the first intermediate stopper layer 26, and a first intermediate stopper layer 26 and a second intermediate interlayer insulating layer 34 on the first intermediate stopper layer 26. In the example embodiment, the second intermediate interlayer insulating layer 34 may include a silicon nitride material different from that of the first intermediate stopper layer 26, and even when the second intermediate interlayer insulating layer 34 may include the same material, a boundary therebetween may be distinct by a difference in physical properties.

Thereafter, similarly to the example described with reference to FIGS. 13A and 13B, a plurality of holes penetrating the second intermediate interlayer insulating layer 34 and the first intermediate stopper layer 26 and exposing an upper surface of the first intermediate interconnection portion 23 may be formed.

Thereafter, similarly to the example described with reference to FIGS. 14A and 14B, a barrier layer 37 conformally covering a surface of the plurality of holes and an upper surface of the second intermediate interlayer insulating layer 34, and a second preliminary intermediate interconnection portion 33′ and a second preliminary intermediate plug 35′ on the barrier layer 37 may be formed.

Referring to FIGS. 17A and 17B, a second intermediate interconnection structure 31 may be formed.

The forming the second intermediate interconnection structure 31 may be configured the same as or similar to the forming the first intermediate interconnection structure 21 described with reference to FIGS. 15A and 15B.

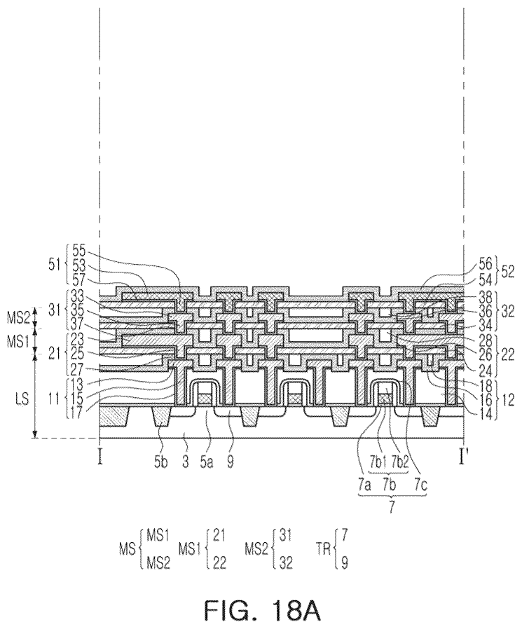

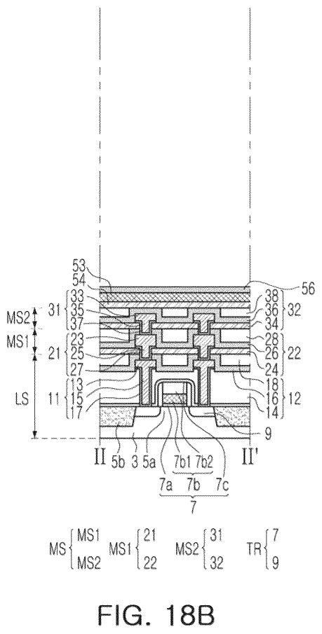

FIGS. 18A and 18B are diagrams illustrating processes of a third cycle for forming a bitline 53 after the processes in FIGS. 17A and 17B. The third cycle may also include processes the same as or similar to the first cycle described with reference to FIGS. 9A to 15B.

Referring to FIGS. 18A and 18B, an upper interconnection structure 51 may be formed on the second intermediate interconnection structure 31, and an upper stopper layer 56 may be formed on the upper interconnection structure 51.

A second intermediate stopper layer 36 covering a second intermediate interlayer insulating layer 34 and a second intermediate interconnection portion 33, a second intermediate gap-fill insulating layer 38 on the second intermediate stopper layer 36, a second intermediate stopper layer 36 and an upper interlayer insulating layer 54 on the second intermediate stopper layer 36, a plurality of holes penetrating the upper interlayer insulating layer 54 and the second intermediate stopper layer 36 and exposing an upper surface of the second intermediate interconnection portion 33, an upper interconnection structure 51 including a barrier layer 57, a contact plug 55, and a bitline 53 on the upper interlayer insulating layer 54, and an upper stopper layer 56 on the upper interconnection structure 51 may be formed.

According to an example embodiment, the upper stopper layer 56 may not be formed on the upper interconnection structure 51.

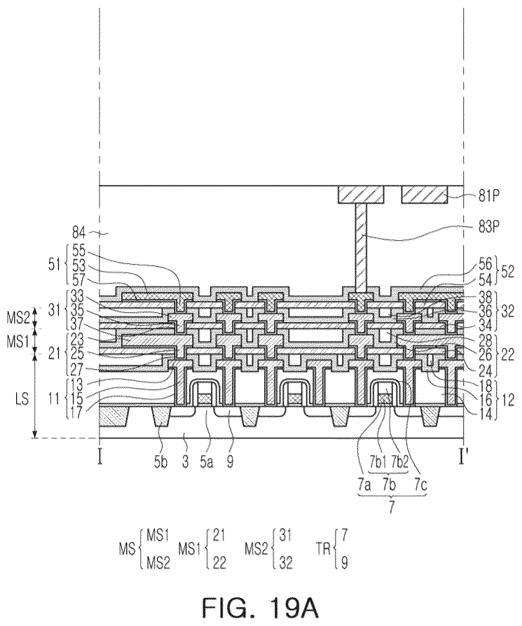

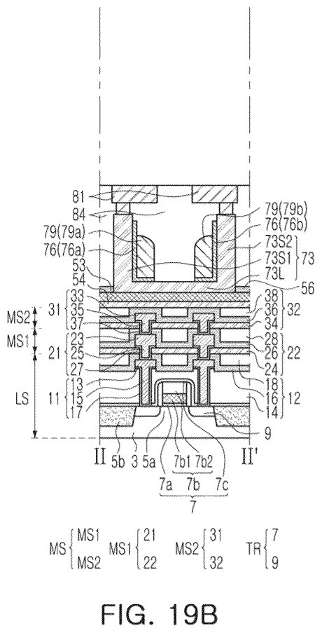

FIGS. 19A to 21B are vertical cross-sectional diagrams illustrating processes for forming an upper transistor and a data storage structure 87 after the processes in FIGS. 18A and 18B.

Referring to FIGS. 19A and 19B, an upper transistor may be formed on bitlines 53.

In the cell array region MCA, the channel structure 73, the dielectric structure 76, the wordlines 79, the landing pads 81 and the upper gap-fill insulating layer 84 may be formed on the bitlines 53 as illustrated in FIG. 3.

In a connection region EA, an upper interconnection 81p and an upper plug 83p may be formed on the bitlines 53 and an upper stopper layer 56. In an example embodiment, an upper interconnection 81p and an upper plug 83p may be formed simultaneously with landing pads 81 and may include the same material as that of the landing pads 81. An upper gap-fill insulating layer 84 may surround the second upper interconnection 81p, the upper interconnection 81p and the upper plug 83p.

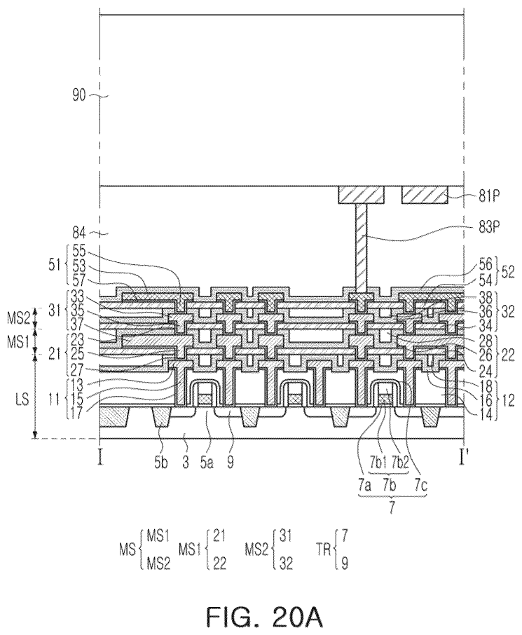

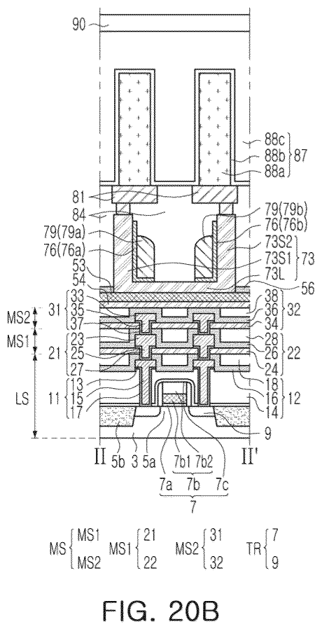

Referring to FIGS. 20A and 20B, a data storage structure 87 may be formed on the upper transistor.

In the cell array region MCA, a data storage structure 87 may be formed on the upper transistor. As described with reference to FIG. 3, the data storage structure 87 may include first electrodes 88a electrically connected to and in contact with the landing pads 81, a second electrode 88c on the first electrodes 88a, and a dielectric layer 88b between the first electrodes 88a and the second electrode 88c.

In the cell array region MCA, an upper insulating structure 90 covering the data storage structure 87 may be formed. The upper insulating structure 90 may cover the upper interconnection 81p in the connection region EA.

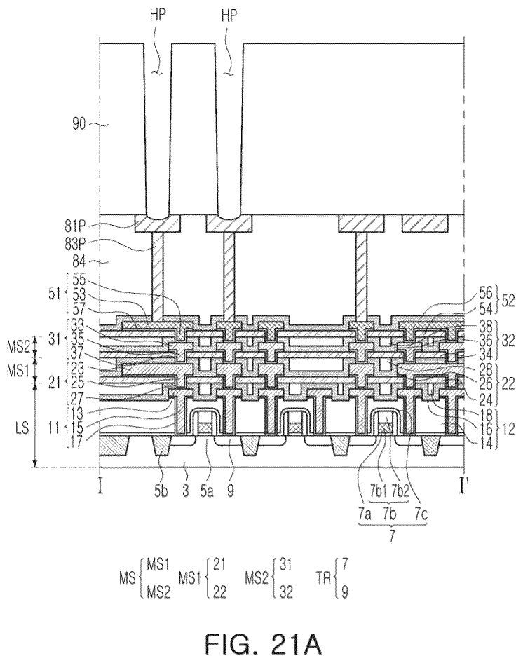

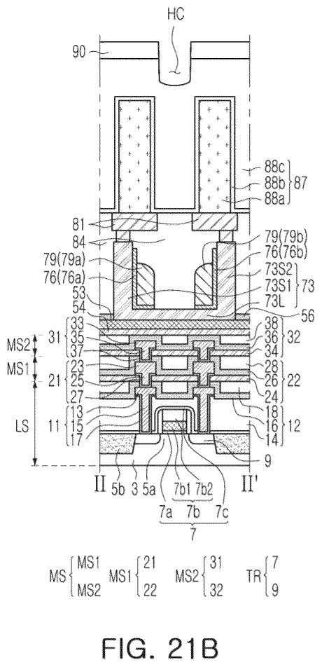

Referring to FIGS. 21A and 21B, a cell contact hole HC may be formed in the cell array region MCA, and a peripheral contact hole HP may be formed in the connection region EA.

The cell contact hole HC may penetrate the upper insulating structure 90 and may expose the second electrode 88c. The peripheral contact hole HP may penetrate the upper insulating structure 90 and may expose an upper surface of the upper interconnection 81p. The cell contact hole HC and the peripheral contact hole HP may be formed simultaneously by performing an anisotropic etching process.

Referring back to FIGS. 2A and 3, a barrier layer 96 may be conformally formed in the cell contact hole HC and the peripheral contact hole HP, and a metal layer 93 may be filled in the barrier layer 96, thereby forming each of a cell contact plug CCP and a peripheral contact plug PCP.

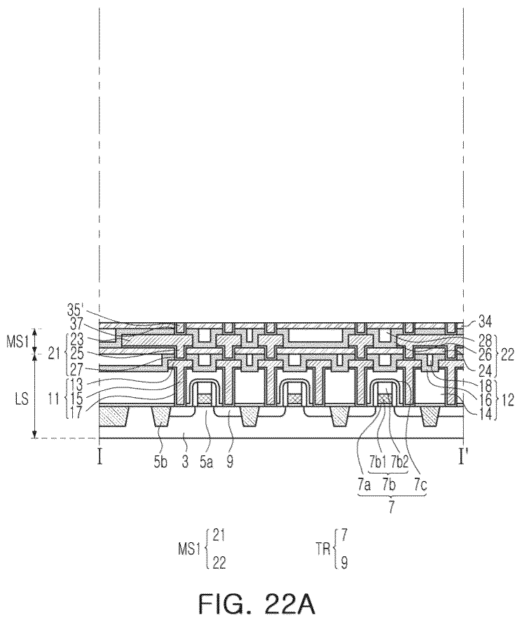

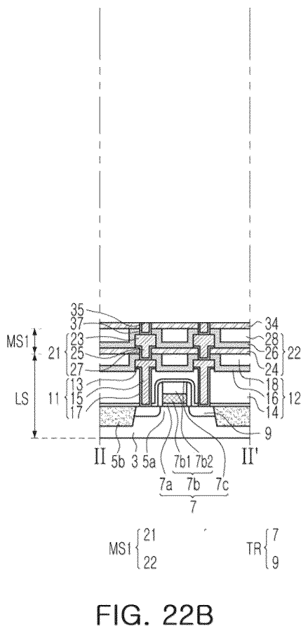

FIGS. 22A to 24B are vertical cross-sectional diagrams illustrating processes of a method of manufacturing a semiconductor device 1b in order according to an example embodiment. FIGS. 22A to 24A are process diagrams illustrating a process continuing from the process in FIG. 16A, and FIGS. 22B to 24B are process diagrams illustrating a process continuing from the process in FIG. 16B.

Referring to FIGS. 22A and 22B, a second preliminary intermediate interconnection portions 33′ as in FIGS. 16A and 16B may be removed through a planarization process such as chemical mechanical polishing (CMP).

Accordingly, an upper surface of the second intermediate interlayer insulating layer 34 and upper surfaces of the second preliminary intermediate plug 35′ may be exposed. The upper surface of the second intermediate interlayer insulating layer 34 and the upper surfaces of the second preliminary intermediate plug 35′ may be formed on the same level.

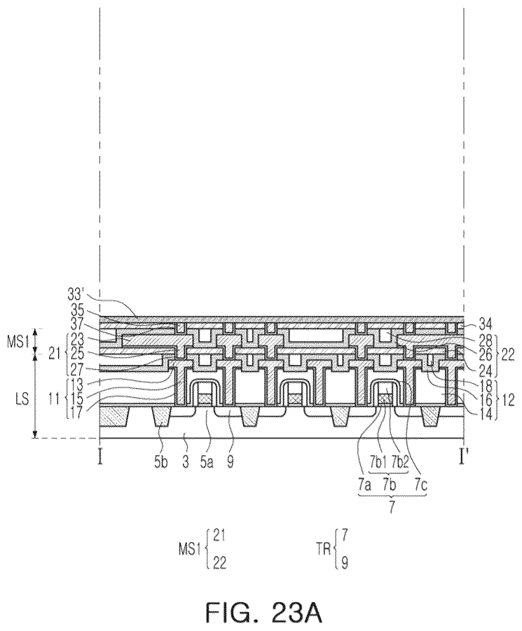

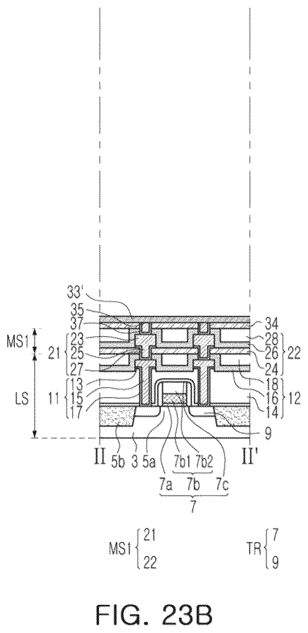

Referring to FIGS. 23A and 23B, a second preliminary intermediate interconnection portion 33′ may be formed on the second intermediate interlayer insulating layer 34 and the second preliminary intermediate plug 35′.

The forming the second preliminary intermediate interconnection portion 33′ may include depositing a conductive material on the second intermediate interlayer insulating layer 34 and the second preliminary intermediate plug 35′. Here, the conductive material may be deposited by physical vapor deposition (PVD).

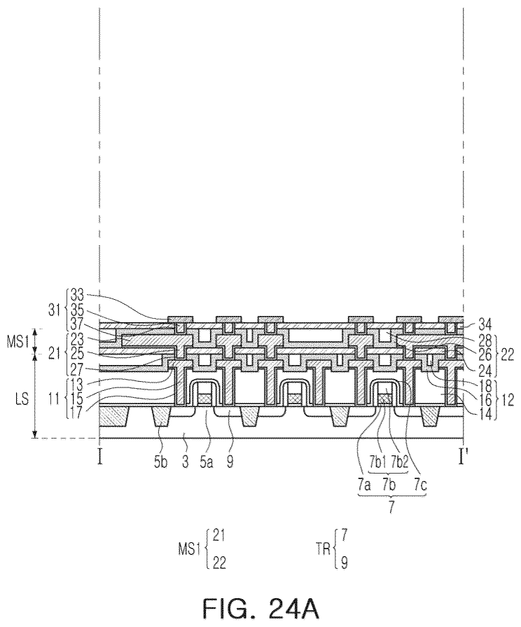

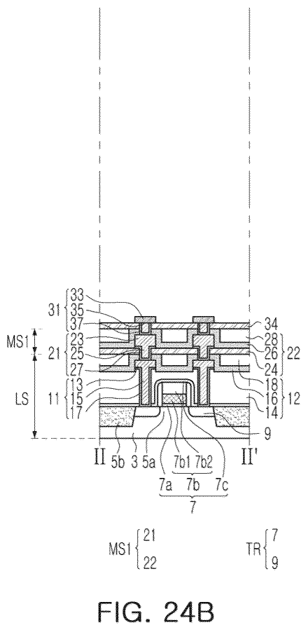

Accordingly, the second intermediate interconnection portion 33 according to FIGS. 24A and 24B may have film quality denser than that of the lower interconnection portion 13 and the first intermediate interconnection portion 23. Accordingly, the second intermediate interconnection portion 33 may have resistance lower than that of the lower interconnection portion 13 and the first intermediate interconnection portion 23.

Referring to FIGS. 24A and 24B, similarly to FIGS. 15A and 15B, a second intermediate interconnection portion 33 may be formed. The detailed descriptions thereof will not be provided.

According to the aforementioned example embodiments, by disposing at least one intermediate structure including an intermediate interconnection structure on a lower structure including an interconnection structure, various interconnection structures may be implemented and flexibility in design may be increased. Accordingly, the area of the connection region may be reduced. Also, as each of the intermediate structures includes a plurality of insulating layers, the level of warpage occurring in the manufacturing process may be addressed or alleviated.

While the example embodiments have been illustrated and described above, it will be configured as apparent to those skilled in the art that modifications and variations may be made without departing from the scope in the example embodiment as defined by the appended claims.

What is claimed is:

1. A semiconductor device comprising:
a lower structure comprising a substrate, and a lower transistor on the substrate;
an intermediate structure on the lower structure; and
an upper structure on the intermediate structure, the upper structure comprising an upper transistor and a data storage structure,
wherein the intermediate structure comprises:
an intermediate interlayer insulating layer on the lower structure;
an intermediate interconnection structure comprising an intermediate plug and an intermediate interconnection portion on the intermediate plug, wherein the intermediate plug penetrates the intermediate interlayer insulating layer;
an intermediate stopper layer comprising an intermediate stopper horizontal portion on the intermediate interlayer insulating layer, and an intermediate stopper extension portion extending from the intermediate stopper horizontal portion and covering a side surface and an upper surface of the intermediate interconnection portion; and
an intermediate gap-fill insulating layer on an external side surface of the intermediate stopper extension portion and on the intermediate stopper horizontal portion of the intermediate stopper layer.

2. The semiconductor device of claim 1,
wherein the intermediate interlayer insulating layer and the intermediate stopper layer comprise a first insulating material, and
wherein the intermediate gap-fill insulating layer comprises a second insulating material different from the first insulating material.

3. The semiconductor device of claim 2,
wherein the intermediate interlayer insulating layer and the intermediate stopper layer comprise an insulating nitride, and
wherein the intermediate gap-fill insulating layer comprises an insulating oxide.

4. The semiconductor device of claim 1, wherein the upper structure further comprises:
an upper interlayer insulating layer on the intermediate stopper extension portion of the intermediate stopper layer and on the intermediate gap-fill insulating layer;
an upper interconnection structure comprising a contact plug penetrating the upper interlayer insulating layer, wherein the contact plug is connected to the intermediate plug and to a bitline on the contact plug; and
an upper stopper layer on the upper interlayer insulating layer and on the upper interconnection structure.

5. The semiconductor device of claim 4,
wherein a side surface of the intermediate gap-fill insulating layer is in contact with the external side surface of the intermediate stopper extension portion, and
wherein an upper surface of the intermediate stopper extension portion and an upper surface of the intermediate gap-fill insulating layer are in contact with a lower surface of the upper interlayer insulating layer.

6. The semiconductor device of claim 4, wherein the upper transistor comprises:
a vertical channel portion on the bitline;
a wordline facing a side surface of the vertical channel portion; and
a dielectric structure between the side surface of the vertical channel portion and the wordline.

7. The semiconductor device of claim 6,
wherein the upper structure further comprises a landing pad on the vertical channel portion, and
wherein the data storage structure is on the landing pad.

8. The semiconductor device of claim 4,
wherein the upper structure further comprises:
an upper gap-fill insulating layer on the upper stopper layer;
an upper plug penetrating the upper gap-fill insulating layer, wherein the upper plug is connected to the bitline;
an upper interconnection on the upper plug; and
an upper insulating structure on the upper gap-fill insulating layer and on the upper interconnection, the upper insulating structure comprising a peripheral plug, and
wherein the peripheral plug penetrates the upper insulating structure and is connected to the upper interconnection.

9. The semiconductor device of claim 4,
wherein the upper structure further comprises an upper insulating structure on the upper stopper layer, the upper insulating structure comprising a peripheral plug, and
wherein the peripheral plug penetrates the upper insulating structure and is connected to the bitline.

10. The semiconductor device of claim 1,
wherein the intermediate interconnection structure further comprises a barrier layer comprising a first portion on a lower surface of the intermediate interconnection portion and a second portion extending along a side surface and a lower surface of the intermediate plug,
wherein a side surface of the first portion of the barrier layer is in contact with the intermediate stopper layer, and
wherein at least a portion of the second portion of the barrier layer is surrounded by the intermediate gap-fill insulating layer and the intermediate interlayer insulating layer.

11. A semiconductor device comprising:
a lower structure comprising a lower transistor;
an intermediate structure on the lower structure; and
an upper structure on the intermediate structure, the upper structure comprising a data storage structure,
wherein the intermediate structure comprises:
a first intermediate interlayer insulating layer;
a first intermediate interconnection structure penetrating the first intermediate interlayer insulating layer, the first intermediate interconnection structure comprising a first intermediate plug and a first intermediate interconnection portion on the first intermediate plug;
a first intermediate stopper layer comprising a first horizontal portion on the first intermediate interlayer insulating layer, and a first extension portion extending from the first horizontal portion, wherein the first extension portion is on a side surface and an upper surface of the first intermediate interconnection structure;
a first intermediate gap-fill insulating layer on an upper surface of the first horizontal portion and on an external side surface of the first extension portion;
a second intermediate interlayer insulating layer on an upper surface of the first extension portion and on an upper surface of the first intermediate gap-fill insulating layer; and
a second intermediate interconnection structure comprising a second intermediate plug and a second intermediate interconnection portion on the second intermediate plug, wherein the second intermediate plug penetrates the second intermediate interlayer insulating layer and the first extension portion and is connected to the first intermediate interconnection portion,
wherein the first intermediate interlayer insulating layer, the first intermediate stopper layer, and the second intermediate interlayer insulating layer comprise an insulating nitride, and
wherein the first intermediate gap-fill insulating layer comprises an insulating oxide.

12. The semiconductor device of claim 11,
wherein the first intermediate interconnection portion extends to the first intermediate plug, and
wherein the second intermediate interconnection portion extends to the second intermediate plug.

13. The semiconductor device of claim 11, wherein a lower surface of the first horizontal portion is on a level lower than a level of a lower surface of the first intermediate interconnection portion.

14. The semiconductor device of claim 13,
wherein the intermediate structure further comprises a second intermediate stopper layer comprising a second horizontal portion on the second intermediate interlayer insulating layer, and a second extension portion extending from the second horizontal portion, wherein the second extension portion is on a side surface and an upper surface of the second intermediate interconnection structure, and
wherein a lower surface of the second horizontal portion is on a level lower than a level of a lower surface of the second intermediate interconnection portion.

15. The semiconductor device of claim 11, wherein an upper surface of the first extension portion is on a level higher than a level of an upper surface of the first intermediate gap-fill insulating layer.

16. The semiconductor device of claim 11,
wherein an upper surface of the first intermediate interconnection portion is concave downwardly, and
wherein the second intermediate plug is in contact with at least a portion of the upper surface of the first intermediate interconnection portion.

17. The semiconductor device of claim 11, wherein a film quality of one of the first and the second intermediate interconnection portions is denser than a film quality of the other of the first and the second intermediate interconnection portions.

18. A semiconductor device comprising:
a lower structure comprising a substrate;
at least one intermediate structure on the lower structure; and
an upper structure on the at least one intermediate structure, the upper structure comprising an upper transistor and a data storage structure on the upper transistor,
wherein the lower structure comprises:
a peripheral transistor on the substrate, the peripheral transistor comprising a peripheral source/drain and a peripheral gate;
a lower interlayer insulating layer on the substrate, wherein the lower interlayer insulating layer covers at least a side surface of the peripheral gate;
a lower interconnection structure comprising a lower plug penetrating the lower interlayer insulating layer, and a lower interconnection portion on the lower plug;
a lower stopper layer on the lower interlayer insulating layer and on the lower interconnection structure, the lower stopper layer comprising a lower stopper horizontal portion on the lower interlayer insulating layer, and a lower stopper extension portion extending from the lower stopper horizontal portion and covering a side surface and an upper surface of the lower interconnection portion; and
a lower gap-fill insulating layer on the lower stopper extension portion,
wherein the at least one intermediate structure comprises:
an intermediate interlayer insulating layer on the lower stopper extension portion and on the lower gap-fill insulating layer;
an intermediate interconnection structure comprising an intermediate plug and an intermediate interconnection portion on the intermediate plug, wherein the intermediate plug penetrates the intermediate interlayer insulating layer and the lower stopper layer;
an intermediate stopper layer on the intermediate interlayer insulating layer and on the intermediate interconnection structure, the intermediate stopper layer comprising an intermediate stopper horizontal portion on the intermediate interlayer insulating layer, and an intermediate stopper extension portion extending from the intermediate stopper horizontal portion and covering a side surface and an upper surface of the intermediate interconnection portion; and
an intermediate gap-fill insulating layer on the intermediate stopper horizontal portion,
wherein the upper structure comprises:
an upper interlayer insulating layer on the intermediate stopper extension portion and on the intermediate gap-fill insulating layer;
an upper interconnection structure comprising a contact plug and a bitline on the contact plug, wherein the contact plug penetrates the upper interlayer insulating layer and is connected to the intermediate plug; and
an upper stopper layer on the upper interlayer insulating layer and on the upper interconnection structure, and
wherein the upper transistor comprises:
a vertical channel portion on the bitline;
a wordline facing a side surface of the vertical channel portion; and
a dielectric structure between the side surface of the vertical channel portion and the wordline.

19. The semiconductor device of claim 18,
wherein the peripheral transistor further comprises an insulating liner covering the peripheral gate on the substrate, and
wherein a lower surface of the lower stopper horizontal portion is on a level lower than a level of an upper surface of the insulating liner.

20. The semiconductor device of claim 18,
wherein the lower gap-fill insulating layer and the intermediate gap-fill insulating layer comprise silicon oxide, and
wherein the lower stopper layer, the intermediate interlayer insulating layer, the intermediate stopper layer, the upper interlayer insulating layer, and the upper stopper layer comprise silicon nitride.
